(19) United States
(12) Patent Application Publication
(10) Pub. No.: US 2015/0221641 A1
(43) Pub. Date: Aug. 6, 2015

(54) SEMICONDUCTOR DEVICE

(71) Applicant: KABUSHIKI KAISHA TOSHIBA, Tokyo (JP)

(72) Inventor: Kazuaki ONISHI, Taishi Hyogo (JP)

(21) Appl. No.: 14/332,526

(22) Filed: Jul. 16, 2014

(30) Foreign Application Priority Data
Feb. 3, 2014 (JP) 2014-018247

(51) Int. Cl. H01L 27/088; H01L 29/739; H01L 29/36; H01L 27/08; H01L 27/082; H01L 29/10; H01L 29/861; H01L 29/78

(52) U.S. Cl. CPC H01L 27/088; H01L 29/861; H01L 29/7397; H01L 29/7813; H01L 27/0814; H01L 27/0823; H01L 29/1095; H01L 29/36

(57) ABSTRACT

According to one embodiment, a semiconductor device includes a first electrode disposed on a first surface of a semiconductor substrate, and a second electrode disposed on a second surface of the semiconductor substrate. The first surface is on an opposite side of the semiconductor substrate from the second surface. A first conductive member is provided on a central portion of the first electrode. A second conductive member is provided on the second electrode. The first conductive member is not disposed on a peripheral portion of the first electrode that is adjacent to the central portion. The electrical resistance of the semiconductor substrate between the central portion of the first electrode and the second electrode is lower than electrical resistance of the substrate between the peripheral portion of the first electrode and the second electrode.

### CROSS-REFERENCE TO RELATED APPLICATION

This application is based upon and claims the benefit of priority from Japanese Patent Application No. 2014-018247, filed Feb. 3, 2014, the entire contents of which are incorporated herein by reference.

### FIELD

Embodiments described herein relate generally to a semiconductor device.

### BACKGROUND

A semiconductor device that includes a vertical element, such as a vertical Insulated Gate Bipolar Transistor (IGBT), a vertical Metal Oxide Semiconductor Field Effect Transistor (MOSFET), or a vertical diode, operates with a voltage applied to the vertical element using electrodes which are provided on both upper and lower surfaces of a semiconductor substrate. In the semiconductor devices that include vertical elements, it is necessary to suppress the local concentration of current and heat during the on-operation (nominally conducting state) and to improve the breakdown resistance of the semiconductor device.

### DESCRIPTION OF THE DRAWINGS

FIG. 1 is a schematic cross-sectional view illustrating a semiconductor device according to a first embodiment.

FIG. 2 is an enlarged view illustrating an area surrounded by the broken line in FIG. 1.

FIG. 3 is a depiction of an operation according to the first embodiment.

FIG. 4 is a further depiction of the operation according to the first embodiment.

FIG. 5 is a schematic cross-sectional view illustrating a semiconductor device according to a second embodiment.

FIG. 6 is a schematic cross-sectional view illustrating a semiconductor device according to a third embodiment.

FIG. 7 is a schematic cross-sectional view illustrating a semiconductor device according to a fourth embodiment.

FIG. 8 is a schematic cross-sectional view illustrating a semiconductor device according to a fifth embodiment.

### DETAILED DESCRIPTION

Exemplary embodiments are described for solving the above problem(s), and exemplary embodiments provide a semiconductor device which is capable of suppressing local concentration of current and heat during an on-operation and improving breakdown resistance.

According to one embodiment, a semiconductor device includes a first electrode disposed on a first surface of a semiconductor substrate, and a second electrode disposed on a second surface of the semiconductor substrate. The first surface is on an opposite side of the semiconductor substrate from the second surface. A first conductive member is provided on a central portion of the first electrode such that the central portion of the first electrode is between the first conductive member and the semiconductor substrate. A second conductive member is provided on the second electrode such that the second electrode is between the second conductive member and the semiconductor substrate. The first conductive member is not disposed on a peripheral portion of the first electrode that is adjacent to the central portion. The electrical resistance of the semiconductor substrate between the central portion of the first electrode and the second electrode is lower than electrical resistance of the substrate between the peripheral portion of the first electrode and the second electrode.

Exemplary embodiments will be described with reference to the accompanying drawings. The same reference numerals used in different drawings in general indicate the same, or substantially similar, components are depicted in the different drawings and the repeated description of such components may be omitted when appropriate.

In the context of the exemplary embodiments, a vertical element refers to elements which in general have a structure in which a current flows from one side surface of a semiconductor substrate toward the other side surface thereof during an on-operation. That is, a vertical element operates electrically across the thickness of the semiconductor substrate such that current flows from what may be considered a first major surface to a second major surface of the semiconductor substrate. The vertical element includes, for example, a vertical IGBT, a vertical MOSFET, a vertical diode, and the like.

In the description herein type, n⁺ type, n type, and n⁻ type indicates that the n type dopant concentrations decrease in this respective order—that is, n⁺ type material has a higher n type dopant concentration than n type material, which in turn has a higher n type dopant concentration than n⁻ type material. In the same manner, the description of p⁺ type material, p type material, and p⁻ type material means that the p type dopant concentrations thereof decrease in this respective order.

An n type dopant is, for example, phosphorus (P) or arsenic (As). In addition, a p type dopant is, for example, boron (B).

In addition, in the exemplary embodiments, “upper” and “lower” are terms that merely define the relative positional relationship between depicted components in the figures and do not necessarily define directions with regard to a gravity direction.

### First Embodiment

According to an embodiment, there is provided a semiconductor device including: a semiconductor substrate that includes a vertical element; a first electrode that is provided on one side of the semiconductor substrate (e.g., upper surface); a second electrode that is provided on another side of the semiconductor substrate (e.g., lower surface); a first conductive member that is provided on a central portion of the upper surface of the first electrode; and a second conductive member that is provided on the lower surface of the second electrode.

During an on-operation of the vertical element, electrical resistance between the first electrode and the second electrode in the vertical element is lower between the central portion (that is, the portion under the first conductive member) of the first electrode and the second electrode than electrical resistance between a peripheral portion (that is, the portion not under the first conductive member) of the first electrode and the second electrode. The peripheral portion of the first electrode is adjacent to the central portion and corresponds to the portion of the first electrode that is not under the first conductive member.

In the semiconductor device according to the first embodiment, unit cells may be provided between the central portion of the first electrode and the second electrode with unit cells not typically being provided between the peripheral portion of the first electrode and the second electrode. With this configuration, the density of the unit cells between the central portion of the first electrode and the second electrode is higher than the density of the unit cells between the peripheral portion of the first electrode and the second electrode.

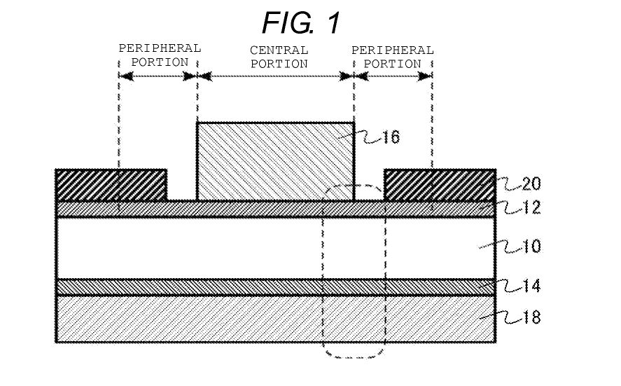

FIG. 1 is a schematic cross-sectional view illustrating the semiconductor device according to the first embodiment. The semiconductor device according to the first embodiment includes a semiconductor substrate 10, a first electrode 12, a second electrode 14, a first conductive member 16, a second conductive member 18, and a protective layer 20.

The semiconductor substrate 10 is, for example, single crystal silicon. An IGBT is provided in the semiconductor substrate 10 as a vertical element.

The first electrode 12 is provided on a first surface (upper surface) of the semiconductor substrate 10. The first electrode 12 is the emitter electrode of the IGBT, in this embodiment. Here, the emitter electrode is formed of metal, for example, a laminated film of titanium (Ti) and aluminum (Al).

The second electrode 14 is provided on the second surface (lower surface) of the semiconductor substrate 10. The second electrode 14 is the collector electrode of the IGBT, in this embodiment. The collector electrode is typically formed of metal, for example, a laminated film of titanium (Ti) and aluminum (Al).

Meanwhile, the semiconductor device also includes the gate electrode of the IGBT, which is not specifically illustrated in the drawing, on the same surface side (e.g., the first surface side) of the substrate 10 as the first electrode 12.

The first conductive member 16 is provided on the central portion of the first electrode 12. The first conductive member 16 is on the upper surface of the first electrode 12. That is, the first electrode 12 is between the first conductive member 16 and the substrate 10. The first conductive member 16 is not necessarily directly provided on the first electrode 12. For example, a solder layer(s) (not specifically illustrated in the drawing) may be interposed therebetween.

The first conductive member 16 functions as a take-out (extraction) electrode to the outside for the emitter electrode 12. In addition, the first conductive member 16 also serves to radiate heat, which is generated by an operation of the IGBT, to the outside. The first conductive member 16 is typically formed of metal, for example, copper (Cu) or a copper alloy.

The second conductive member 18 is provided on the same side of substrate 10 as the second electrode 14 with the second conductive member 18 provided on the lower surface of the second electrode 14. That is, the second electrode 14 is between the substrate 10 and the second conductive member 18. The second conductive member 18 may extend in a lateral direction (along the primary plane of substrate 10 beyond the first conductive member 16), as depicted in FIG. 1. The second conductive member 18 is not necessarily provided directly under the second electrode 14. For example, a solder layer(s) (not specifically illustrated in the drawing) may be interposed therebetween.

The second conductive member 18 functions as a take-out (extraction) electrode to the outside for the collector electrode 14. In addition, the second conductive member 18 also serves to radiate heat, which is generated by the operation of the IGBT, to the outside. The second conductive member 18 is typically formed of metal, for example, copper (Cu) or a copper alloy.

The protective layer 20 is provided on the upper surface of the first electrode 12. As depicted in FIG. 1, the first conductive member 16 is provided in an opening formed in or by protective layer 20. The protective layer 20 is formed of, for example, polyimide.

In the semiconductor device according to the first embodiment, during an on-operation of the vertical element, electrical resistance between the central portion of the first electrode (emitter electrode) 12 and the second electrode (collector electrode) 14 is lower than the electrical resistance between the peripheral portion of the first electrode 12 and the second electrode 14.

Here, the peripheral portion of the first electrode 12 means a predetermined area possibly ranging from directly under the edge (end part) of the first conductive member 16 to the edge (end part) of the semiconductor device. For example, a breakdown voltage modifying structure, such as a guard ring, can be provided in the semiconductor substrate 10 in the peripheral portion of the first electrode 12. The peripheral portion of the first electrode 12 need not range to the edge of the semiconductor device, but rather, for example, may be an area ranging from the end part of the first conductive member 16 to the protective layer 20.

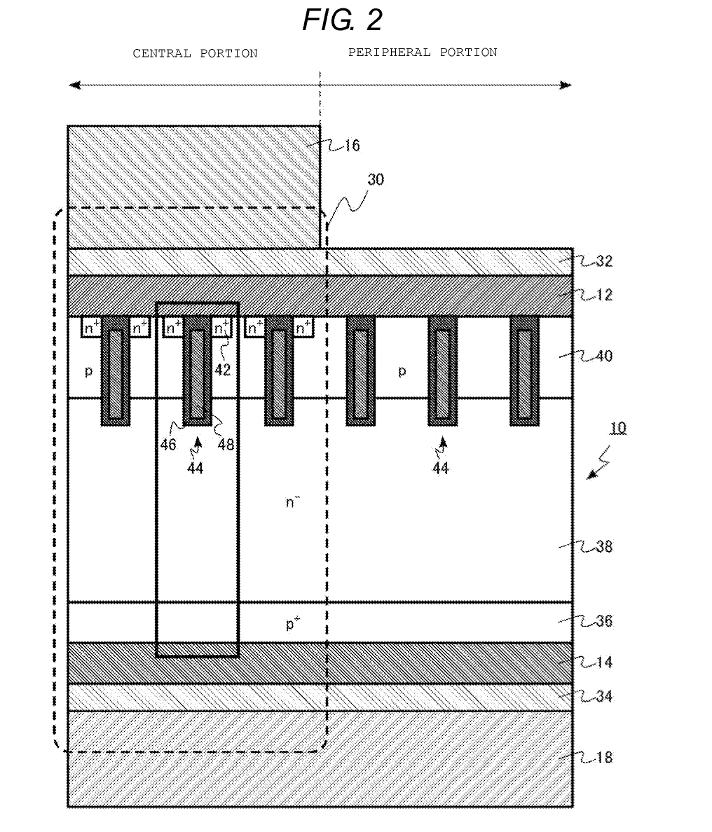

FIG. 2 is an enlarged view illustrating the area surrounded by the broken line in FIG. 1. As illustrated in FIG. 2, the semiconductor substrate 10 includes an IGBT (vertical element) 30 which includes a plurality of unit cells. A unit cell of the IGBT corresponds to an area which is surrounded by a rectangle frame of a solid line in FIG. 2.

The emitter electrode 12 is provided on one side surface (first surface) of the semiconductor substrate 10. The collector electrode 14 is provided on the other side surface (second surface) of the semiconductor substrate 10.

The first conductive member 16 is provided over the central portion of the first electrode 12 with a solder layer 32 interposed therebetween. The second conductive member 18 is provided under the second electrode 14 with a solder layer 34 interposed therebetween.

A p⁺ type collector layer 36 is provided in the semiconductor substrate 10 for electrical connection with the collector electrode 14. Further, an n⁻ type drift layer 38 is provided on the p⁺ type collector layer 36. It is preferable that the p⁺ type collector layer 36 and the collector electrode 14 are connected in a manner of ohmic contact.

In addition, a p type base layer 40 is provided on the n⁻ type drift layer 38. Further, an n⁻ type emitter layer 42 is selectively provided on the p type base layer 40. The n⁻ type emitter layer 42 contacts the emitter electrode 12. In this embodiment, the n⁺ type emitter layer 42 and the emitter electrode 12 are connected in a manner of ohmic contact. In addition, the p type base layer 40 and the emitter electrode 12 are also connected in a manner of ohmic contact.

In the semiconductor substrate 10, trenches 44 are formed from the first surface of the substrate 10 and extending into the substrate 10 towards the collector electrode 14. The trenches 44 include upper ends which are located in the p type base layer 40 or the n⁺ type emitter layer 42, and include lower ends which are located in the n⁻ type drift layer 38.

A gate insulating film 46 and a gate layer (electrode) 48 are provided in the trench 44. The gate layer 48 is provided with the gate insulating film 46 interposed between the gate layer 48 and the p type base layer 40. The semiconductor device according to this example embodiment has a trench gate structure in which the IGBT element is controlled to be on or off using a voltage applied to the gate layer in the trench.

The gate insulating film 46 is, for example, a silicon thermal oxide film. In addition, the gate layer 48 is, for example, polycrystalline silicon doped with an n type dopant. The n⁺ type emitter layer 42 in this embodiment is contacts the gate insulating film 46 on a side surface of the trench 44.

The portions of the n⁺ type emitter layer 42, the p type base layer 40, the n⁻ type drift layer 38, the p⁺ type collector layer 36, the gate insulating film 46 and the gate layer 48 within the solid line rectangle of FIG. 2 constitute a unit cell of the IGBT. As depicted in FIG. 2, three unit cells are provided under first conductive member 16.

In the semiconductor device according to the first embodiment, the plurality of unit cells of the IGBT are provided in the semiconductor substrate 10 between the central portion of the emitter electrode 12 and the collector electrode 14. On the other hand, unit cells are not provided in the semiconductor substrate 10 between the peripheral portion of the emitter electrode 12 and the collector electrode 14.

Although the trenches 44 are provided in the semiconductor substrate 10 between the peripheral portion of the emitter electrode 12 and the collector electrode 14, the n⁺ type emitter layer 42 is not provided in this region. Therefore, the trenches 44 between the peripheral portion of the emitter electrode 12 and the collector electrode 14 are so-called “dummy” trenches which are not involved in the on-operation or the off-operation of the vertical element.

Because the unit cells are not provided between the peripheral portion of the emitter electrode 12 and the collector electrode 14, the electrical resistance between the central portion of the emitter electrode 12 and the collector electrode 14 is generally lower than the electrical resistance between the peripheral portion of the emitter electrode 12 and the collector electrode 14 during the on-operation of the IGBT. The reason for this is that a channel which has low resistance is not formed on the side surface of the trenches 44 in the peripheral portion because the unit cells are not present between the peripheral portion of the emitter electrode 12 and collector electrode 14.

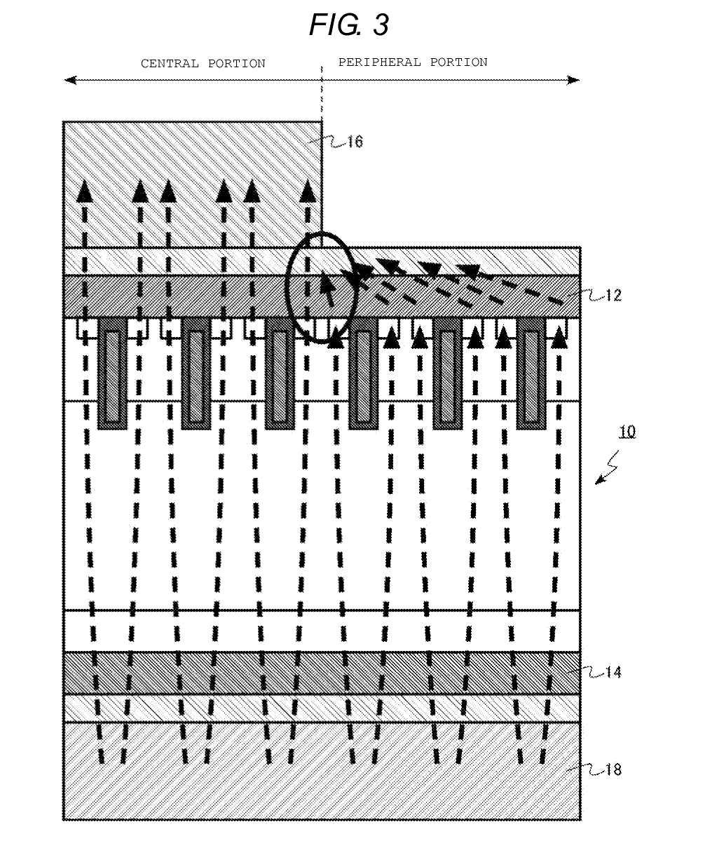

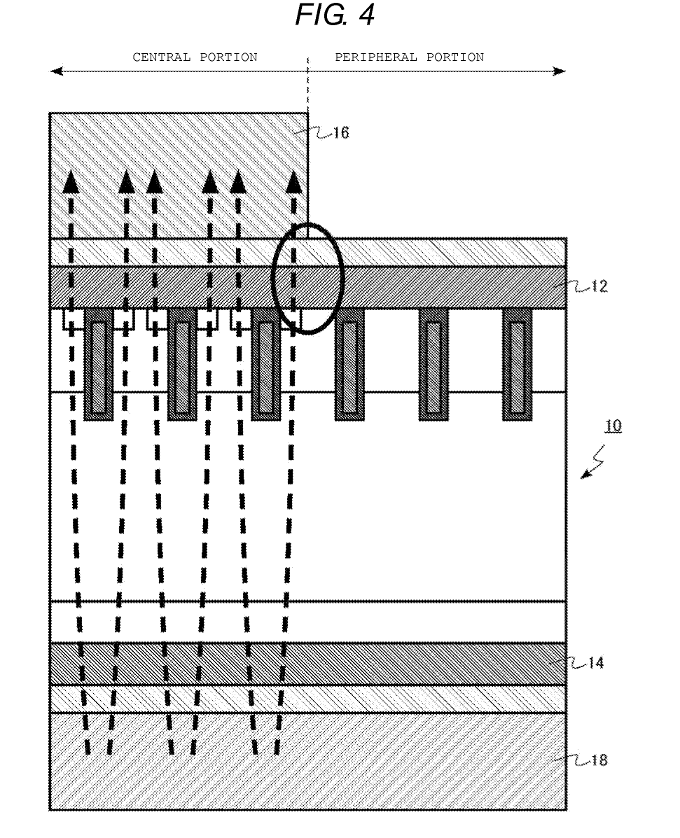

FIGS. 3 and 4 are explanatory views illustrating the operation of the first embodiment. FIG. 3 illustrates a schematic cross section of a semiconductor device according to a comparison embodiment. FIG. 4 is a schematic cross section of the semiconductor device according to the first embodiment.

The semiconductor device of FIG. 3 is different from the semiconductor device according to the first embodiment in that a plurality of unit cells are provided between the peripheral portion of the emitter electrode 12 and the collector electrode 14. In these drawings, dotted arrows indicate notional current paths during the on-operation of the IGBT.

In a case of the semiconductor device of FIG. 3, the electrical current is concentrated in the vicinity of the boundary (i.e., the area surrounded by the ellipse in FIG. 3) between the central portion and the peripheral portion of the emitter electrode 12. Therefore, a localized heating becomes large in the vicinity of the boundary between the central portion and the peripheral portion of the emitter electrode 12.

In addition, the first conductive member 16 which radiates generated heat to the outside is not present on the peripheral portion of the emitter electrode 12. Therefore, the radiation of generated heat is relatively slow. Accordingly, temperature becomes extremely high because of the generation of heat due to current concentration and slow radiation of heat in the vicinity of the boundary between the central portion and the peripheral portion of the emitter electrode 12, and thus a possibility that the element is broken is increased.

In contrast, as illustrated in FIG. 4, in the semiconductor device according to the embodiment, the current does significantly not flow between the peripheral portion of the emitter electrode 12 and the collector electrode 14. Therefore, the current is not concentrated in the vicinity of the boundary between the central portion and the peripheral portion of the emitter electrode 12, and thus it is possible to avoid extreme rising of temperature. Therefore, the possibility that the element is broken is reduced, and thus the breakdown resistance of the semiconductor device is improved.

Thus, a semiconductor device in which the local concentration of the current and heat during the on-operation is suppressed is provided. Such a semiconductor device improved breakdown resistance. That is, such a semiconductor device has high reliability.

### Second Embodiment

A semiconductor device according to a second embodiment is the same as in the first embodiment except that at least one cell is present between the peripheral portion of the first electrode and the second electrode, though the density of the unit cells between the central portion of the first electrode and the second electrode is higher than the density of the unit cells between the peripheral portion of the first electrode and the second electrode.

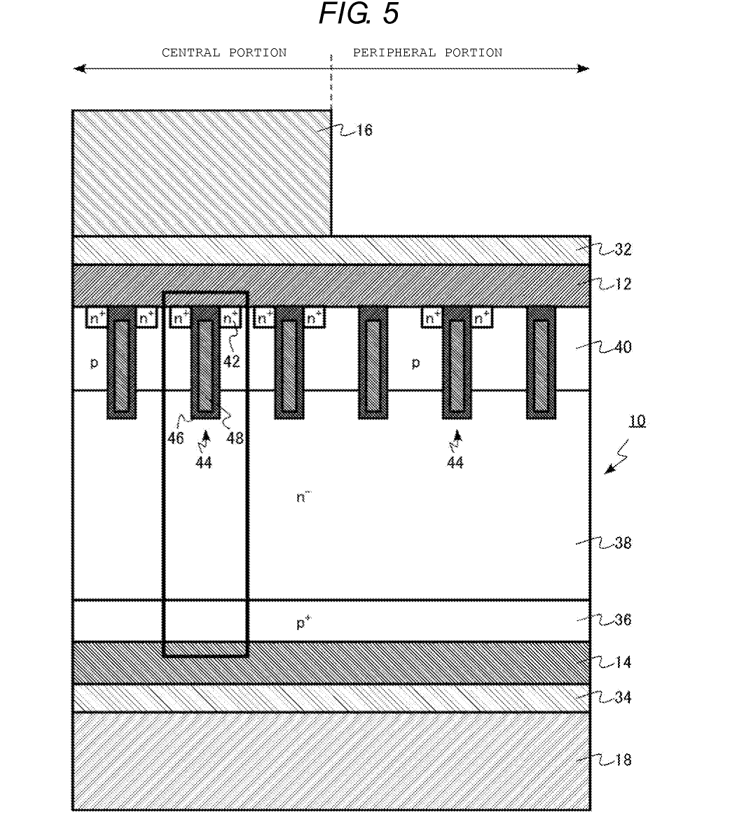

FIG. 5 is a schematic cross-sectional view illustrating the semiconductor device according to the embodiment. As illustrated in FIG. 5, a unit cell is provided in the semiconductor substrate 10 between the peripheral portion of the emitter electrode (first electrode) 12 and the collector electrode (second electrode) 14. While only a single unit cell is depicted in the peripheral portion in FIG. 5, multiple unit cells may be provided in the peripheral portion of this second embodiment; however, in the peripheral portion of this second embodiment the unit cells are relatively sparse compared with density of unit cells between the central portion of the emitter electrode (first electrode) 12 and the collector electrode (second electrode) 14. That is, the unit cells are provided such that the number of unit cells per unit area directly under the peripheral portion of the emitter electrode 12 is less than the number of unit cells per unit area directly under the central portion of the emitter electrode 12.

In the second embodiment, since a unit cell(s) are present between the peripheral portion of the emitter electrode 12 and the collector electrode 14, the current flows in the peripheral portion during the on-operation of the IGBT. However, since the unit cells are relatively sparse, the concentration of the current in the vicinity of the boundary between the central portion and the peripheral portion of the emitter electrode 12 is reduced as compared to the comparison embodiment in FIG. 3.

Accordingly, as compared to the comparison embodiment in FIG. 3, the possibility that the element is broken is reduced, and thus the breakdown resistance of the semiconductor device is improved. In addition, as compared to the first embodiment, it is possible to increase an on-state current as the semiconductor device.

Thus, according to the second embodiment, a semiconductor device in which the local concentration of the current or heat during the on-operation is suppressed and improved breakdown resistance is provided. That is, the semiconductor device which has high reliability is realized. In addition, as compared to the first embodiment, it is possible to increase the on-state current.

### Third Embodiment

A semiconductor device according to a third embodiment is similar to the first embodiment except that the vertical element is a MOSFET rather than an IGBT.

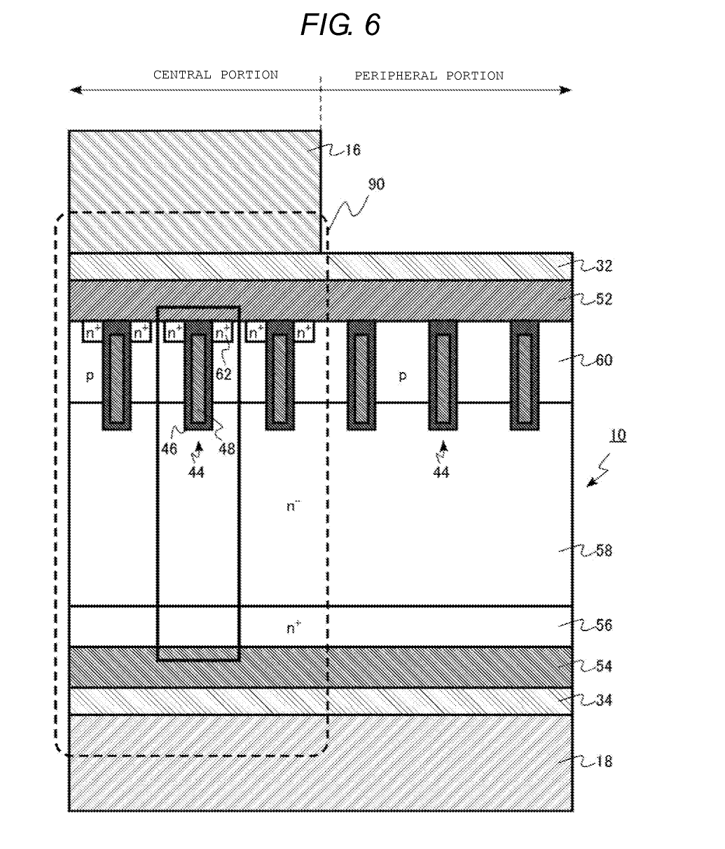

FIG. 6 is a schematic cross-sectional view illustrating the semiconductor device according to the third embodiment. As illustrated in FIG. 6, the semiconductor substrate 10 includes a MOSFET (vertical element) 90 that includes a plurality of unit cells. A unit cell of the MOSFET is an area which is surrounded by a rectangle frame of a solid line in FIG. 6.

In the embodiment, a source electrode (first electrode) 52 is provided on one side surface (first surface) of the semiconductor substrate 10. A drain electrode (second electrode) 54 is provided on the other side surface (second surface) of the semiconductor substrate 10.

A first conductive member 16 is provided on the source electrode 52 with a solder layer 32 interposed therebetween. A second conductive member 18 is provided under the drain electrode 54 with a solder layer 34 interposed therebetween.

An n⁺ type drain layer 56 is provided on the drain electrode 54 of the semiconductor substrate 10. Further, an n⁻ type drift layer 58 is provided on the n⁺ type drain layer 56.

In addition, a p type channel layer 60 is provided on the n⁻ type drift layer 58. Further, an n⁺ type source layer 62 is provided on the p type channel layer 60. The p type channel layer 60 and the n⁺ type source layer 62 come into contact with the source electrode 52.

A trench 44 is formed from the first surface of the semiconductor substrate extending into the semiconductor substrate 10. The trench 44 includes an upper end, which is located in the p type channel layer 60 or the n⁺ type source layer 62, and a lower end which is located in the n⁻ type drift layer 58.

Agate insulating film 46 and a gate layer 48 are provided in the trench 44. The gate layer 48 is provided in the p type channel layer 60 with the gate insulating film 46 interposed therebetween. The semiconductor device according to the third embodiment has a trench gate structure in which the element is controlled to be on or off using a voltage applied to the gate layer 48 in the trench.

The gate insulating film 46 is, for example, a silicon thermal oxide film. In addition, the gate layer 48 is, for example, polycrystalline silicon in which an n type dopant is doped. The n⁺ type source layer 62 is provided to come into contact with the gate insulating film 46 on a side surface of the trench 44.

The portions of n⁺ type source layer 62, the p type channel layer 60, the n⁻ type drift layer 58, the p⁺ type drain layer 56, the gate insulating film 46, and the gate layer 48 with the solid rectangular frame in FIG. 6 constitute a unit cell of the MOSFET.

In the semiconductor device according to the embodiment, a plurality (e.g., three as depicted in FIG. 6) of unit cells (the area which is surrounded by the rectangle frame of the solid line in FIG. 6) of the MOSFET is provided in the semiconductor substrate 10 between the central portion of the source electrode 52 and the drain electrode 54. On the other hand, unit cells are not provided in the semiconductor substrate 10 between the peripheral portion of the source electrode 52 and the drain electrode 54.

Because the unit cells are not provided between the peripheral portion of the source electrode 52 and the drain electrode 54, the electrical resistance between the central portion of the source electrode 52 and the drain electrode 54 is lower than the electrical resistance between the peripheral portion of the source electrode 52 and the drain electrode 54 during an on-operation of the MOSFET.

In the semiconductor device according to the third embodiment, the current does not flow between the peripheral portion of the source electrode 52 and the drain electrode 54. Therefore, the concentration of the current is not generated in the vicinity of the boundary between the central portion and the peripheral portion of the source electrode 52, and thus it is possible to avoid extreme rising of temperature. Accordingly, the possibility that the element is broken is reduced, and thus the breakdown resistance of the semiconductor device is improved.

According to the third embodiment, a semiconductor device, in which the local concentration of the current or heat during the on-operation is suppressed and with an improved breakdown resistance is provided. That is, a semiconductor device which has high reliability is implemented.

### Fourth Embodiment

A semiconductor device according to a fourth embodiment is different from the first embodiment in that a vertical element is a diode and in that the dopant concentration of a semiconductor substrate which comes into contact with a first electrode between the central portion of the first electrode and a second electrode is generally higher than the dopant concentration of the semiconductor substrate 10 which comes into contact with the first electrode between the peripheral portion of the first electrode and the second electrode.

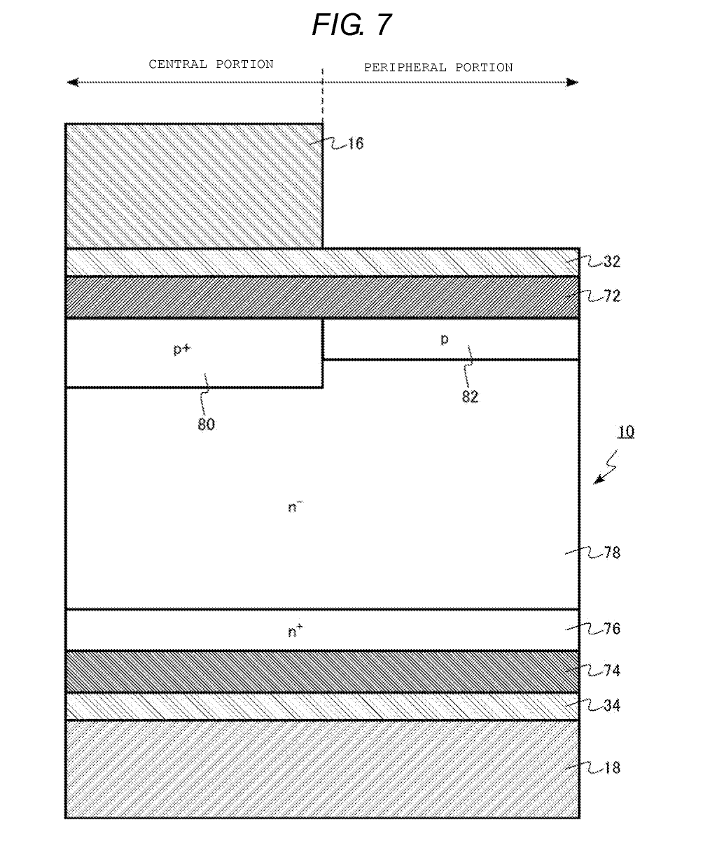

FIG. 7 is a schematic cross-sectional view illustrating the semiconductor device according to the fourth embodiment. FIG. 7 illustrates a vertical element that is a PN diode.

In the embodiment, an anode electrode (first electrode) 72 is provided on one side surface (first surface) of the semiconductor substrate 10. A cathode electrode (second electrode) 74 is provided on the other side surface (second surface) of the semiconductor substrate 10.

A first conductive member 16 is provided on the anode electrode 72 with a solder layer 32 interposed therebetween. A second conductive member 18 is provided under the cathode electrode 74 with a solder layer 34 interposed therebetween.

An n⁺ layer 76 is provided on the cathode electrode 74 of the semiconductor substrate 10. Further, an n⁻ type drift layer 78 is provided on the n⁺ layer 76.

In addition, a p⁺ layer 80 is provided on the n⁻ type drift layer 78 of the semiconductor substrate 10 between the central portion of the anode electrode 72 and the cathode electrode 74. The p⁺ layer 80 comes into contact with the anode electrode 72.

A p layer 82 is provided on the n⁻ type drift layer 78 of the semiconductor substrate 10 between the peripheral portion of the anode electrode 72 and the cathode electrode 74. The p layer 82 comes into contact with the anode electrode 72. The p layer 82 in this embodiment is connected to the anode electrode 72 in a manner of ohmic contact.

The p layer 82 has a p type dopant concentration lower than that of the p⁺ layer 80. Therefore, the dopant concentration of the semiconductor substrate 10 which comes into contact with the anode electrode 72 between the central portion of the anode electrode 72 and the cathode electrode 74 is higher than the dopant concentration of the semiconductor substrate 10 which comes into contact with the anode electrode 72 between the peripheral portion of the anode electrode 72 and the cathode electrode 74.

Therefore, the electrical resistance between the central portion of the anode electrode 72 and the cathode electrode 74 during an on-operation of the PN diode is lower than the electrical resistance between the peripheral portion of the anode electrode 72 and the cathode electrode 74.

In the semiconductor device according to the fourth embodiment, the current which flows between the peripheral portion of the anode electrode 72 and the cathode electrode 74 is reduced. Therefore, the current is less prone to be concentrated in the vicinity of the boundary between the central portion and the peripheral portion of the anode electrode 72, and thus it is possible to avoid an extreme rising of temperature. Therefore, the possibility that the element is broken is reduced, and thus the breakdown resistance of the semiconductor device is improved.

According to the fourth embodiment, the semiconductor device, in which the local concentration of the current or heat during the on-operation is suppressed and breakdown resistance is improved, is realized. That is, a semiconductor device which has high reliability is implemented.

### Fifth Embodiment

A semiconductor device according to a fifth embodiment is similar to the fourth embodiment excepting that an impurity layer is which comes into contact with the first electrode is selectively provided between the peripheral portion of the first electrode and a second electrode.

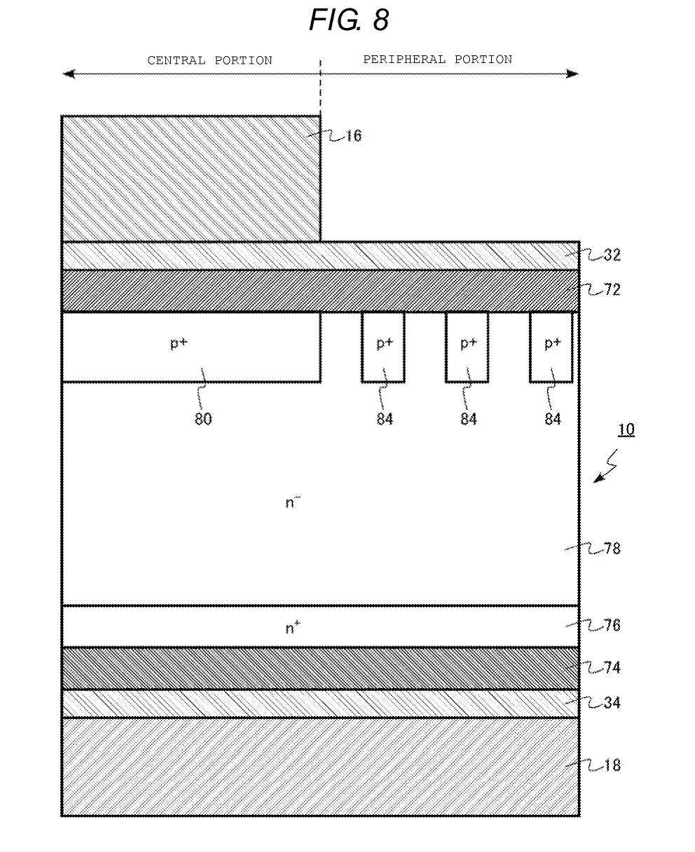

FIG. 8 is a schematic cross-sectional view illustrating the semiconductor device according to the fifth embodiment. A vertical element according to the fifth embodiment is a PN diode.

In the fifth embodiment, a p⁺ layer 80 is provided on the n⁻ type drift layer 78 of the semiconductor substrate 10 between the central portion of the anode electrode 72 and the cathode electrode 74. The p⁺ layer 80 comes into contact with the anode electrode 72.

A plurality of p⁺ layers 84 are selectively provided on the n⁻ type drift layer 78 of the semiconductor substrate 10 between the peripheral portion of the anode electrode 72 and the cathode electrode 74.

The p⁺ layers 84 have, for example, a p type dopant concentration which is the same as that of the p⁺ layer 80. Therefore, the average dopant concentration of the semiconductor substrate 10 which comes into contact with the anode electrode 72 between the central portion of the anode electrode 72 and the cathode electrode 74 is higher than the average dopant concentration of the semiconductor substrate 10 which comes into contact with the anode electrode 72 between the peripheral portion of the anode electrode 72 and the cathode electrode 74.

Therefore, the electrical resistance between the central portion of the anode electrode 72 and the cathode electrode 74 during an on-operation of the PN diode is lower than the electrical resistance between the peripheral portion of the anode electrode 72 and the cathode electrode 74.

In the semiconductor device according to the fifth embodiment, the current which flows between the peripheral portion of the anode electrode 72 and the cathode electrode 74 is reduced. Therefore, current is less prone to be concentrated in the vicinity of the boundary between the central portion and the peripheral portion of the anode electrode 72, and thus it is possible to avoid extreme rising of temperature. Therefore, the possibility that the element is broken is reduced, and thus the breakdown resistance of the semiconductor device is improved.

According to the fifth embodiment, a semiconductor device in which the local concentration of the current or heat during the on-operation is suppressed and with improved breakdown resistance is provided. That is, a semiconductor device which has high reliability is implemented.

Hereinbefore, in the embodiments, the IGBT, the MOSFET, and the diode that include the n type drift layer are described as examples. However, a configuration that includes a p type drift layer is applicable. That is, a configuration that includes an IGBT, a MOSFET, and a diode in which the n type and the p type are switched in the embodiments is also applicable.

In addition, in the embodiments, the single crystal silicon is described as an example of the materials of the semiconductor substrate and the semiconductor layer. However, it is also possible to use other materials as the semiconductor; for example, silicon carbide, gallium nitride, and the like, to the exemplary embodiments.

In addition, in the embodiments, the trench gate type MOSFET and IGBT are described as examples. However, it is also possible to apply the exemplary embodiment to planar-type MOSFET and IGBT.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a semiconductor substrate that includes a vertical element;
a first electrode disposed on a first surface of a semiconductor substrate;
a second electrode disposed on a second surface of the semiconductor substrate, the first surface being on an opposite side of the semiconductor substrate from the second surface;
a first conductive member disposed on a central portion of the first electrode such that the central portion of the first electrode is between the first conductive member and the semiconductor substrate; and
a second conductive member disposed on the second electrode such that the second electrode is between the second conductive member and the semiconductor substrate,
wherein the first conductive member is not disposed on a peripheral portion of the first electrode that is adjacent to the central portion, and
electrical resistance of the semiconductor substrate between the central portion of the first electrode and the second electrode is lower than electrical resistance of the substrate between the peripheral portion of the first electrode and the second electrode.

2. The device according to claim 1, wherein the semiconductor substrate includes a vertical element between the first and second electrodes.

3. The device according to claim 2, wherein the vertical element is between the second electrode and the central portion of the first electrode.

4. The device according to claim 2, wherein the vertical element comprises an insulated gate bipolar transistor (IGBT).

5. The device according to claim 2, wherein the vertical element is comprised of a plurality of insulated gate bipolar transistors disposed along a direction that is parallel to the first surface.

6. The device according to claim 5, wherein there are no insulated gate bipolar transistors between the second electrode and the peripheral portion of the first electrode.

7. The device according to claim 5, wherein at least one insulated gate bipolar transistor is between the second electrode and the peripheral portion of the first electrode, and a density of insulated gate bipolar transistors between the second electrode and the peripheral portion of the first electrode is less than a density of insulated gate bipolar transistors between the second electrode and the central portion of the first electrode.

8. The device according to claim 2, wherein the vertical element comprises a metal-oxide-semiconductor field effect transistor (MOSFET).

9. The device according to claim 2, wherein the vertical element is comprised of a plurality of metal-oxide-semiconductor field (MOSFET) disposed along a direction that is parallel to the first surface.

10. The device according to claim 9, wherein there are no MOSFETs between the second electrode and the peripheral portion of the first electrode.

11. The device according to claim 9, wherein at least one MOSFET is between the second electrode and the peripheral portion of the first electrode, and a density of MOSFETs between the second electrode and the peripheral portion of the first electrode is less than a density of MOSFETs between the second electrode and the central portion of the first electrode.

12. The device according to claim 2, wherein the vertical element includes a trench gate structure.

13. The device according to claim 1, wherein a dopant concentration in a first portion of the semiconductor substrate that is in contact with the central portion the first electrode and between the central portion of the first electrode and the second electrode is greater than a dopant concentration in a second portion of the semiconductor substrate that is in contact with the peripheral portion of the first electrode and between the peripheral portion of the first electrode and the second electrode.

14. The device according to claim 13, wherein
the semiconductor substrate includes a vertical element between the first and second electrodes, and
the vertical element is a diode.

15. A semiconductor device, comprising:
a first electrode disposed on a first surface of a semiconductor substrate;
a second electrode disposed on a second surface of the semiconductor substrate, the first and second surfaces on opposite sides of the semiconductor substrate;
a first conductive member disposed on a central portion of the first electrode such that the central portion of the first electrode is between the first conductive member and the semiconductor substrate;
a second conductive member disposed on the second electrode such that the second electrode is between the second conductive member and the semiconductor substrate; and
a plurality of transistors disposed in the semiconductor substrate between the second electrode and the central portion of the first electrode,
wherein the first conductive member is not disposed on a peripheral portion of the first electrode that is adjacent to the central portion.

16. The device according to claim 15, wherein gate electrodes of transistors in the plurality of transistors are provided as a trench gate structure, the trench gate structure extending from the first surface of the semiconductor substrate into to the semiconductor substrate.

17. The device according to claim 15, wherein no transistor is provided between the second electrode and the peripheral portion of the first electrode.

18. The device according to claim 15, wherein at least one transistor is provided between the second electrode and the peripheral portion of the first electrode, but a density of transistors between the second electrode and the central portion of the first electrode is greater than a density of transistors between the second electrode and the peripheral portion of the first electrode.

19. A semiconductor device, comprising:
a first electrode disposed on a first surface of a semiconductor substrate;
a second electrode disposed on a second surface of the semiconductor substrate, the first and second surfaces on opposite sides of the semiconductor substrate;
a first conductive member disposed on a central portion of the first electrode such that the first electrode is between the first conductive member and the semiconductor substrate; and
a second conductive member disposed on the second electrode such that the second electrode is between the second conductive member and the semiconductor substrate,
wherein the first conductive member is not disposed on a peripheral portion of the first electrode that is adjacent to the central portion, and
a first conductivity dopant concentration in a first portion of the semiconductor substrate that is in contact with the central portion the first electrode and between the central portion of the first electrode and the second electrode is greater than a first conductivity type dopant concentration in a second portion of the semiconductor substrate that is in contact with the peripheral portion of the first electrode and between the peripheral portion of the first electrode and the second electrode.

20. The device according to claim 19, the second portion including:
a plurality of first conductivity type doped regions spaced from each other in a direction parallel to the first surfaces, and
a plurality of second conductivity type doped regions between the first conductivity type doped regions, such that first conductivity dopant concentration of the second portion is less than the first conductivity dopant concentration of the first portion.
